(19) United States
(12) Patent Application Publication
(10) Pub. No.: US 2009/0032883 A1
(43) Pub. Date: Feb. 5, 2009

(54) SEMICONDUCTOR DEVICE

(75) Inventors: Koji WATANABE, Kanagawa (JP); Motoyuki Sato, Tokyo (JP)

Correspondence Address: YOUNG & THOMPSON, 209 Madison Street, Suite 500, ALEXANDRIA, VA, 22314, US

(73) Assignee: NEC ELECTRONICS CORPORATION, Kanagawa (JP)

(21) Appl. No.: 12/183,138

(22) Filed: Jul. 31, 2008

(30) Foreign Application Priority Data
Aug. 2, 2007 (JP) 2007-201713

(51) Int. Cl. H01L 27/092; H01L 29/78

(52) U.S. Cl. 257/369; 257/411; 257/E29.255; 257/E27.062

(57) ABSTRACT

Disclosed is a semiconductor device which comprises one or more metal-insulator-semiconductor field effect transistors (MISFETs), each including: a gate insulating film composed of a silicon oxide film, a first hafnium-containing nitrided silicate film, and a second hafnium-containing nitrided silicate film which are sequentially deposited on a substrate; and a gate structure having an electrode consisting of a metal silicide deposited on the gate insulating film. The first hafnium-containing nitrided silicate film has a hafnium concentration in a range from 5 to 10% and has a nitrogen concentration in a range from 5 to 10%. The second hafnium-containing nitrided silicate film has a hafnium concentration in a range from 50 to 60% and has a nitrogen concentration in a range from 20 to 45%. The gate insulating film has a thickness in a range from 1.8 to 3.0 nm.

This application is based on Japanese patent application No. 2007-201713, the content of which is incorporated herein by reference.

### BACKGROUND

1. Technical Field

The present invention relates to a semiconductor device. More specifically, the present invention relates to a semiconductor device including an element having a metal insulator semiconductor (MIS) structure, such as a field effect transistor and the like.

2. Related Art

In recent years, a number of technologies for producing gate insulating films having reduced electric thickness are investigated for providing improved transistor performances. Two approaches for providing reduced electric film thickness are useful: one is for providing a reduced physical film thickness of a gate insulating film, and the other is for inhibiting an electronic depletion of a gate electrode. Conventionally, a silicon oxide film or a silicon oxynitride film is employed for a material of a general gate insulating film. In recent years, an increased gate leakage current of a gate insulating film, namely a silicon oxide film or a silicon oxynitride film has been a significant problem, in addition to the reduction in the film thickness thereof. Polysilicon is often employed for a general gate electrode material, and while a reduction the film thickness of a gate insulating film is proceeded in the present time, the thickness of the depleted layer formed in the side of the electrode on the interface between polysilicon and the gate insulating film is increased to a nonnegligible thickness (10 to 20% or higher), as compared with the thickness of the gate insulating film, which leads to a significant problem.

An approach for solving the above-described problem may be a use of an oxide containing metallic element for a material of a gate insulating film, in place of the conventional silicon oxide film-base material. Typical metallic elements available in the above-described approach include zirconium (Zr), hafnium (Hf), aluminum (Al), lanthanum (La) and the like. Oxides of such metals are known as high dielectric constant materials, and thus insulating film having larger physical thickness may also be utilized so as to obtain the same electric thickness due to its dielectric constant ratio.

On the contrary, an approach to employ a metallic electrode in place of the conventional polysilicon electrode is proposed for inhibiting an electronic depletion of a gate electrode. In particular, typical one of approaches for forming metallic electrodes is an investigation of a technology for fully silicided (FUSI) gate electrode that is formed by silicidizing a gate electrode to an interface with a gate insulating film, which is adaptable with the commonly employed manufacturing process. Since a combination of the FUSI and the aforementioned material for a gate insulating film having higher dielectric constant achieves reducing the film thickness and reducing the gate leakage current, a number of researches are made in such technical field.

Japanese Patent Application Publication No. 2005-251785 discloses an insulating film having higher dielectric constant composed of a multiple-layered structure, which is manufactured by forming a nitrogen-implanted layer and a nitridation-preventing layer in an insulating film having higher dielectric constant. It is disclosed that, according to Japanese Patent Application Publication No. 2005-251785, a penetrating of impurity can be inhibited without deteriorating properties of the device such as a leakage characteristics of a gate insulating film or a mobility, by selectively introducing nitrogen into only nitridation-targeted regions.

Japanese Patent Application Publication No. 2005-64032 discloses a technology for suitably controlling a metal content and nitrogen content in metal silicon nitride oxide film to introduce metals at higher level in the side of the electrode and nitrogen at higher level in the side of the substrate. It is disclosed that, in the Japanese Patent Application Publication No. 2005-64032, a gate insulating film having a higher dielectric constant and creating no grain boundary after a thermal processing at 1000 degree C. or higher can be formed, even if a concentration of silicon atom in the metal silicon nitride oxide film is increased.

U.S. Pat. No. 6,291,867 discloses a technology for removing a low dielectric constant interfacial layer formed in an interface and provide a grading profile of a silicon-to-metal ratio of metal silicon oxynitride layer from the substrate side to the electrode side. U.S. Pat. No. 6,291,867 discloses a method for achieving a lower leakage current and better electrical characteristics by providing an increased concentration of silicon atom in the metal silicon oxynitride layer in the side of the interface of the silicon substrate and removing the interface layer.

U.S. Pat. No. 6,809,370 discloses a technology for providing a uniform nitrogen concentration profile for nitrogen contained in a metal silicon oxynitride film. U.S. Pat. No. 6,809,370 discloses a method for obtaining improved electrical characteristics by controlling nitrogen concentration in the metal silicon oxynitride film to be about 3 atomic percent or more, nitrogen concentration variation to be about 4 atomic percent or less, and a nitrogen concentration in an interface portion between the dielectric material and the channel to be about 3 atomic percent or less.

Methods for employing a control for composition of nickel silicide are proposed in the following two documents: 1) K. Takahashi, K. Manabe, T. Ikarashi, N. Ikarashi, T. Hase, T. Yoshihara, H. Watanabe, T. Tatsumi, and Y. Mochizuki, “Dual Workfunction Ni-Silicide/HfSiON Gate Stacks by Phase-Controlled Full-Silicidation (PC-FUSI) Technique for 45 nm-node LSTP and LOP Devices”, IEEE International Electron Devices Meeting (IEDM) Technical Digest, pp. 91-94, 2004; and 2) M. Terai, K. Takahashi, K. Manabe, T. Hase, T. Ogura, M. Saitoh, T. Iwamoto, T. Tatsumi, and H. Watanabe, “Highly reliable HfSiON CMOSFET with phase controlled NiSi (NFET) and Ni₃/Si (PFET) FUSI gate electrode”, Symposium on VLSI Technology Digest of Technical Papers, pp. 68-69, 2005. Specifically, nickel disilicide is employed for a gate electrode for an n-type transistor, trinickel silicide is employed for a gate electrode for a p-type transistor, and hafnium-containing nitrided silicate film is employed for a gate insulating film. The number of silicon-hafnium bonds in an interface between the electrode and the gate insulating film is adjusted to control a threshold.

As described above, methods for employing a gate insulating film having higher dielectric constant and a metallic electrode to achieve a reduced leakage current and a reduced film thickness have been conventionally proposed. In particular, a method for suitably controlling a composition or concentration profile in a gate insulating film having higher dielectric constant to provide improved characteristics of transistors, and a method for employing a composition-controlling full silicidation (FUSI) technology for a metallic electrode to achieve a threshold control are proposed.

Nevertheless, the following problems are caused in the technologies described in the above-described prior art documents. The first problem is a difficulty in balancing lower leakage current with higher mobility. In order to reduce a leakage current, it is necessary to increase a dielectric constant by selecting an increased concentration of metal in metal oxide employed for a gate insulating film having higher dielectric constant. On the other hand, a presence of a metallic element may possibly deteriorate mobility of carrier travelling through a channel, due to remote Coulomb scattering.

U.S. Pat. No. 6,809,370 discloses a configuration for controlling a nitrogen concentration in the high-K dielectric material film and the interface portion with the channel to be about 3 atomic percent or less. However, in case of such structure, higher mobility cannot be achieved due to an influence of remote Coulomb scattering by the presence of metallic elements. The second problem is that the structure exhibiting an increased metal content in the side of the electrode in the high-k insulating film disclosed in U.S. Pat. No. 6,291,867, which can achieve a reduced influence of remote Coulomb scattering by a presence of a metal, exhibits a decreased dielectric constant in the region of higher silicon concentration to increase leakage current. In order to solve such problem, Japanese Patent Application Publication No. 2005-64032 discloses a method for increasing nitrogen concentration in vicinity of the substrate interface to obtain higher in vicinity of the interface. However, in such method, atomic nitrogen generates fixed charge, leading to a reduced mobility of carrier. Further, in consideration of such influence of nitrogen, Japanese Patent Application Publication No. 2005-251785 discloses the insulating film having higher dielectric constant composed of a multiple-layered structure having a nitrogen-implanted layer and a nitridation-preventing layer formed therein. However, an increased silicon concentration is required for forming the nitridation-preventing layer, resulting in a decreased dielectric constant in the gate insulating film, and thus a leakage current is increased. The above-described problem may also be occurred when the fully silicided electrodes described in the above-described Transaction of IEDM 2004 and the Digest paper of Symposium on VLSI Technology 2005 are employed to reduce the thickness. In particular, in the structure having a combination of the metallic electrode and the gate insulating film having higher dielectric constant, it is extremely difficult to balance lower leakage current and higher mobility in a region where an inverted capacitance-equivalent thickness of the gate insulating film is equal to or smaller than 2.5 nm.

In view of the foregoing, the present invention is to provide a semiconductor device that exhibits lower leakage current and higher mobility.

### SUMMARY

According to one aspect of the present invention, there is provided a semiconductor device comprising one or more metal-insulator-semiconductor field effect transistors (MISFETs), each including: a gate insulating film composed of a silicon oxide film, a first hafnium-containing nitrided silicate film, and a second hafnium-containing nitrided silicate film which are sequentially deposited on a substrate; and a gate structure having an electrode consisting of a metal silicide deposited on the gate insulating film. The first hafnium-containing nitrided silicate film has a hafnium concentration in a range from 5 to 10% and has a nitrogen concentration in a range from 5 to 10%. The second hafnium-containing nitrided silicate film has a hafnium concentration in a range from 50 to 60% and has a nitrogen concentration in a range from 20 to 45%. The gate insulating film has a thickness in a range of from 1.8 to 3.0 nm.

The semiconductor device is configured that, when the hafnium-containing nitrided silicate film having smaller thickness is employed for the gate insulating film of the MISFET, hafnium concentration and nitrogen concentration in the first hafnium-containing nitrided silicate film that constitutes the gate insulating film and is located in the side of the substrate are reduced, and hafnium concentration and nitrogen concentration in the second hafnium-containing nitrided silicate film that is located in the side of the electrode are increased. This allows reducing the leakage current and improving the mobility in the region where the inverted capacitance-equivalent thickness of the MISFET is equal to or smaller than 2.5 nm.

According to the present invention, a semiconductor device that exhibits lower leakage current and higher mobility can be provided.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a cross-sectional view of a semiconductor device according to first embodiment in the present invention;

FIG. 2 is a schematic diagram, illustrating a manufacturing process for a semiconductor device according to an embodiment of the present invention;

FIG. 3 is a schematic diagram, illustrating a manufacturing process for a semiconductor device according to an embodiment of the present invention;

FIG. 4 is a schematic diagram, illustrating a manufacturing process for a semiconductor device according to an embodiment of the present invention;

FIG. 5 is a schematic diagram, illustrating a manufacturing process for a semiconductor device according to an embodiment of the present invention;

FIG. 6 is a schematic diagram, illustrating a manufacturing process for a semiconductor device according to an embodiment of the present invention;

FIG. 7 is a schematic diagram, illustrating a manufacturing process for a semiconductor device according to an embodiment of the present invention;

FIG. 8 is a schematic diagram, illustrating a manufacturing process for a semiconductor device according to an embodiment of the present invention;

FIG. 9 is a schematic diagram, illustrating a manufacturing process for a semiconductor device according to an embodiment of the present invention;

FIG. 10 includes graphs, showing relationship of leakage current change and mobility of MISFET device over thickness of oxide film;

FIG. 11 is a graph, useful in describing the leakage current change in the present invention;

FIG. 12 is a graph, useful in describing the mobility in the present invention;

FIG. 13 includes graphs, showing relationship of leakage current change and mobility of MISFET device over thickness of thickness of the first hafnium-containing nitrided silicate film;

FIG. 14 includes graphs, showing relationship of leakage current change and mobility of MISFET device over the hafnium concentration in the first hafnium-containing nitrided silicate film;

FIG. 15 includes graphs, showing relationship of reliability and mobility of MISFET device over the nitrogen concentration in the first hafnium-containing nitrided silicate film;

FIG. 16 includes graphs, showing relationship of leakage current change and mobility of MISFET device over thickness of thickness of the second hafnium-containing nitrided silicate film;

FIG. 17 includes graphs, showing relationship of reliability and leakage current change of MISFET device over the hafnium concentration in the second hafnium-containing nitrided silicate film;

FIG. 18 includes graphs, showing relationship of reliability and leakage current change of the MISFET device over the nitrogen concentration in the second hafnium-containing nitrided silicate film;

FIG. 19 is a graph, showing relationship of the inverted capacitance-equivalent thickness and the leakage current of the n-type MISFET device for the gate insulating film structures;

FIG. 20 is a graph, showing relationship of the inverted capacitance-equivalent thickness and the surface carrier mobility of the n-type MISFET device for the gate insulating film structures; and

FIG. 21 is a graph, showing threshold voltages for the material of the gate electrode.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Exemplary implementations according to the present invention will be described in detail as follows in reference to the annexed figures. In all figures, an identical numeral is assigned to an element commonly appeared in the figures, and the detailed description thereof will not be repeated.

### First Embodiment

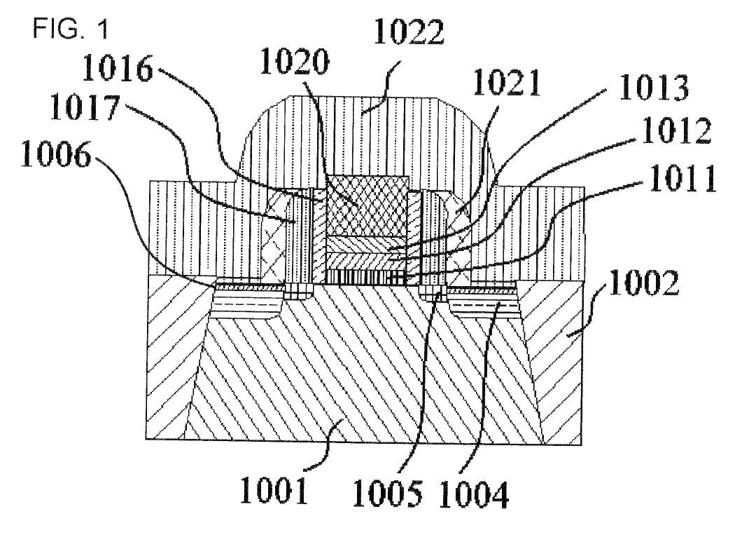

FIG. 1 is a cross-sectional view, illustrating an embodiment of a semiconductor device of the present invention. A semiconductor device in the present embodiment includes a silicon substrate 1001, an element isolating region 1002 having a configuration of shallow trench isolation (STI), a silicon oxide film 1011, a first hafnium-containing nitrided silicate film 1012, a second hafnium-containing nitrided silicate film 1013, a metal silicide gate electrode 1020, a gate side wall 1017, a source-drain region 1004, an extension halo 1005 and a silicon nitride film 1022.

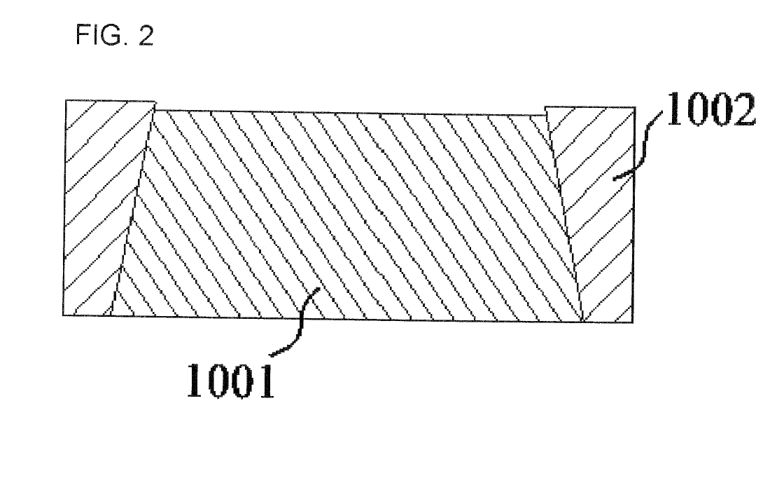

Such structure is manufactured according to a procedure illustrated in FIG. 2 to FIG. 9. Specifically, the element isolating region 1002 is formed over the silicon substrate 1001 (FIG. 2), and then, in the element region, the silicon oxide film 1011, the first hafnium-containing nitrided silicate film 1012 and the second hafnium-containing nitrided silicate film 1013 are deposited as gate insulating films, the gate polysilicon electrode 1014 is deposited as a gate electrode, and the silicon nitride film 1015 is deposited as a hard mask to form the top thereof. Here, films containing hafnium and nitrogen at different hafnium concentration and different nitrogen concentration are employed for the first and the second hafnium-containing nitrided silicate films 1012 and 1013. More specifically, hafnium concentration is selected to be 6% and nitrogen concentration is selected to be 5% for the hafnium-containing nitrided silicate film 1012, and hafnium concentration is selected to be 60% and nitrogen concentration is selected to be 30% for the hafnium-containing nitrided silicate film 1013.

Here, an example of a specific process for depositing a film and its conditions related to the gate insulating film for achieving the structure as set forth in the present invention will be described as follows.

First of all, a cleaning process with hydrofluoric acid solution is conducted before forming the gate insulating film, and then a silicon oxide film 1011 serving as a base film is formed via a thermal oxidation process to have a thickness of 1.6 nm. Next, a hafnium-containing nitrided silicate film is deposited via a metal organic chemical vapor deposition (MO-CVD) process. In such case, the deposition is conducted with source gases of diethyl silane (DES) and tetra diethylamino hafnium (TDEAH) at a substrate temperature of 600 degree C.

In the present example, a deposition is conducted for 30 seconds under the conditions of: DES flow rate of 50 mg/min; TDEAH flow rate of 3 sccm (standard cubic centimeter per minute); oxygen flow rate of 2,000 sccm; and at total pressure of 8 Torr, to deposit a hafnium silicate film containing hafnium at a concentration of 6%. Next, nitrogen is introduced into such hafnium silicate film via a plasma nitridation process.

Such process is conducted for 20 seconds under the conditions of: N₂ gas flow rate of 200 sccm; at an electric power of 600 W; and at a pressure of 20 mTorr. Thus, the first hafnium-containing nitrided silicate film 1012 having a thickness of 1.0 nm with hafnium concentration of 6% and nitrogen concentration of 5% is manufactured by the above-described process. Subsequently, a deposition is conducted for 50 seconds under the conditions of: DES flow rate of 6 mg/min; TDEAH flow rate of 3 sccm; oxygen flow rate of 2,000 sccm; and at total pressure of 7.5 Torr, to deposit a hafnium silicate film containing hafnium at a concentration of 60%. Next, nitrogen is introduced into the hafnium silicate film via a plasma nitridation process. Such process is conducted for 180 seconds under the conditions of: N₂ gas flow rate of 200 sccm; at an electric power of 600 W; and at a pressure of 20 mTorr. Thus, the second hafnium-containing nitrided silicate film 1013 having a thickness of 1.0 nm with hafnium concentration of 60% and nitrogen concentration of 30% is manufactured by the above-described process. Finally, an annealing process is conducted for 10 seconds under the conditions of nitrogen flow rate of 20 slm (standard liter per minute) at a pressure of 740 Torr and at a temperature of 1000 degree C. Such annealing process causes atomic counter diffusions in an interface between the silicon oxide film 1011 and the first hafnium-containing nitrided silicate film 1012 and in an interface between the first hafnium-containing nitrided silicate film 1012 and the second hafnium-containing nitrided silicate film 1013, thereby providing smooth distribution of composition.

Here, the hafnium-containing nitrided silicate film can be deposited with an accuracy in the thickness of equal to or smaller than 0.1 nm by suitably adjusting the processing time, the substrate temperature, the pressure, and the like. The hafnium concentration in the hafnium-containing nitrided silicate film can also be suitably controlled within a range of from 0% to 100% by suitably adjusting ratio of flow rates of source gases. The nitrogen content in the hafnium-containing nitrided silicate film can be controlled to be within a range of from 0% to 60% by suitably adjusting power, pressure and processing time.

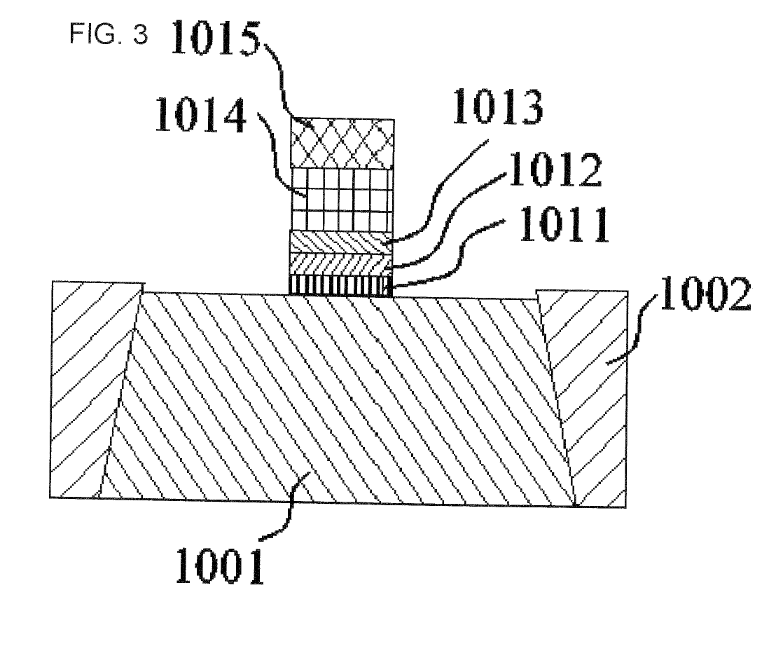

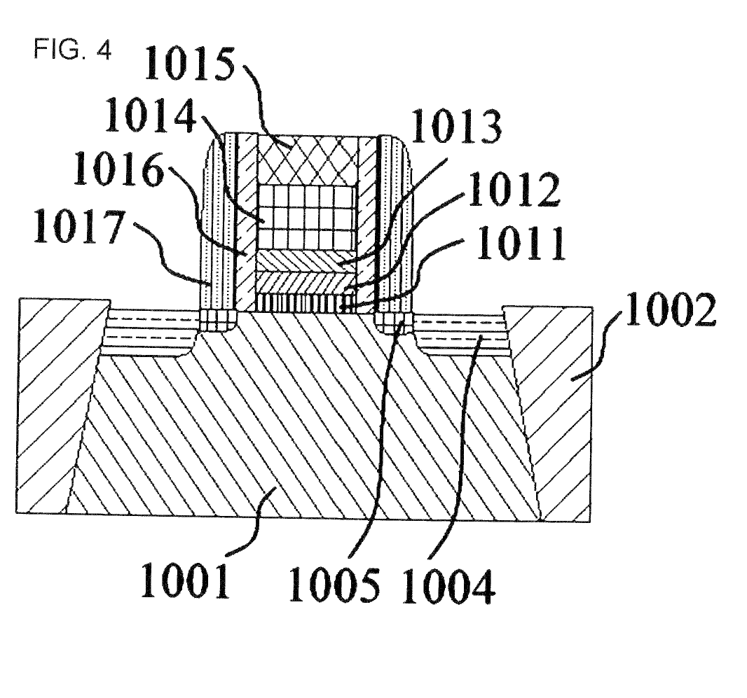

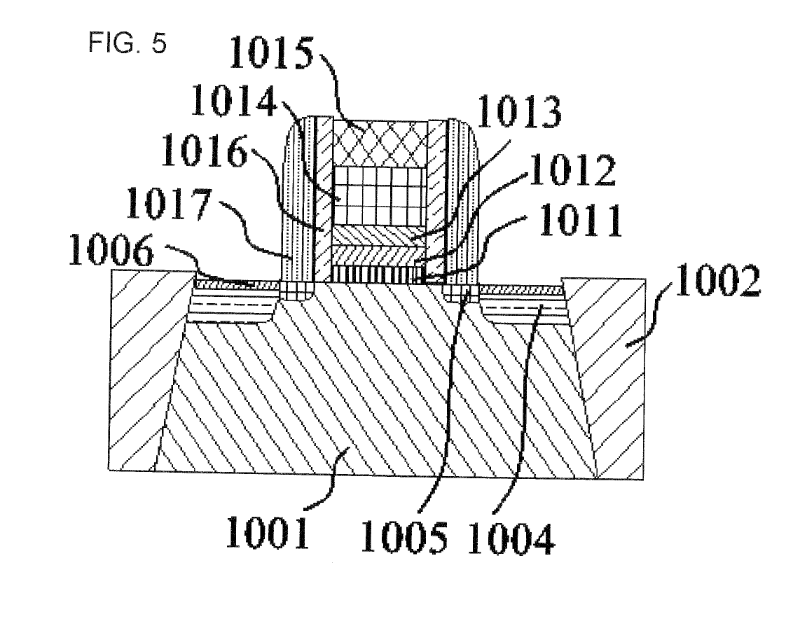

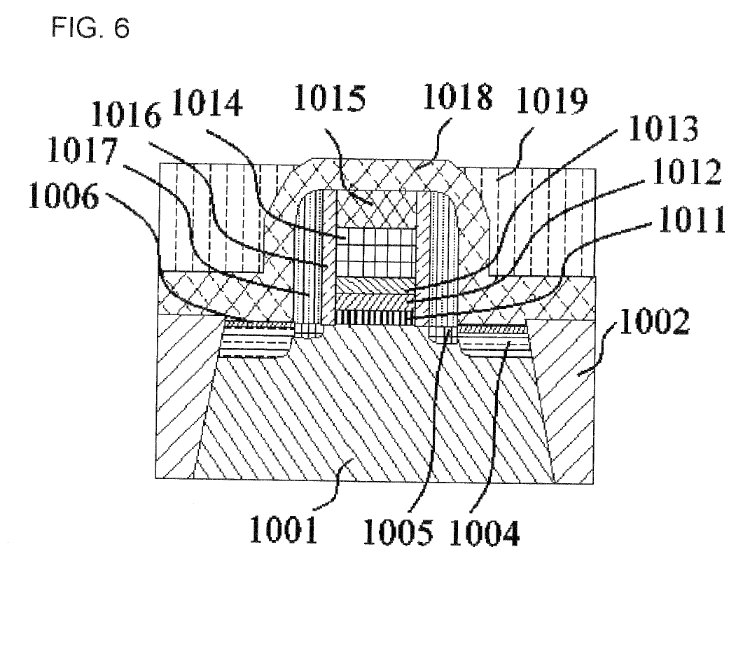

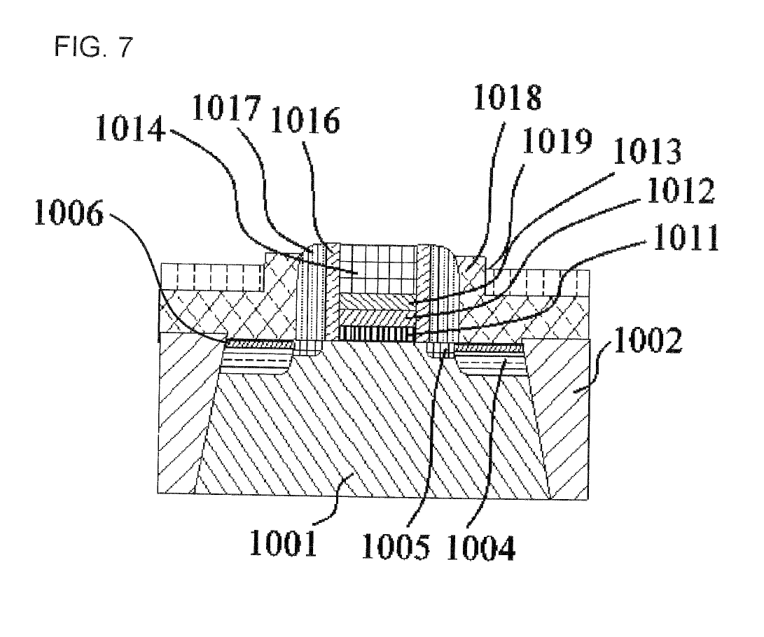

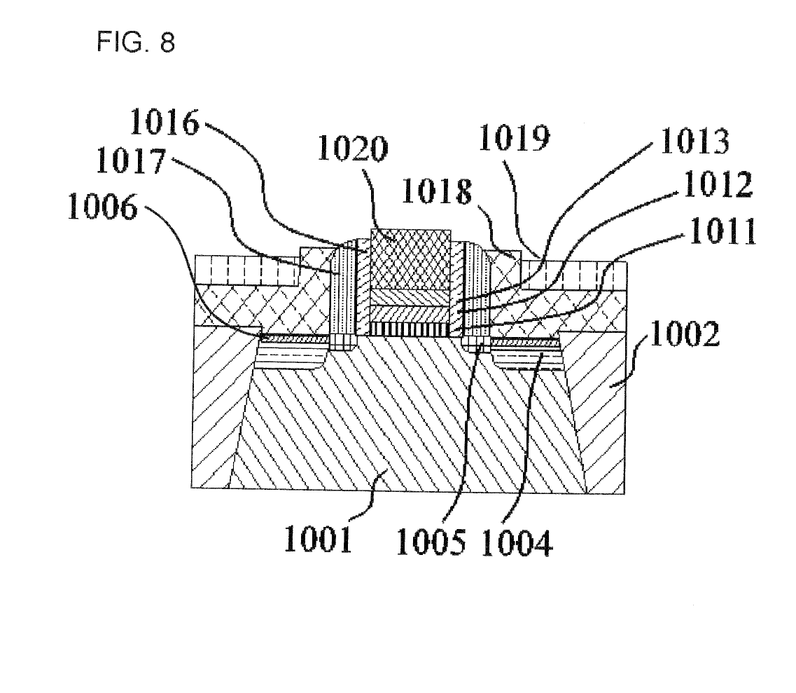

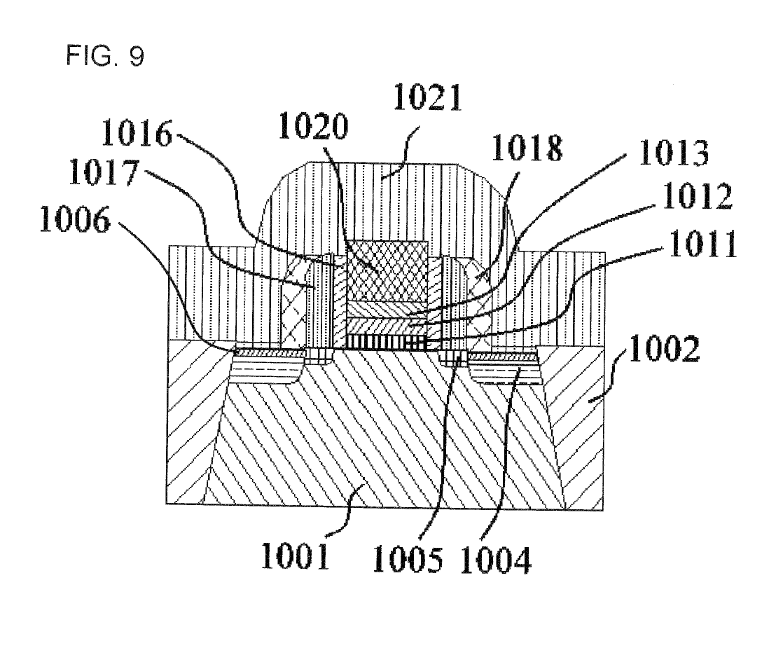

Thereafter, an etching process is conducted (FIG. 3) to form an offset spacer 1016, thereby forming an extension halo 1005, a gate side wall 1017 and a source-drain region 1004, (FIG. 4). Next, a silicide layer 1006 is formed on the source-drain region 1004 (FIG. 5). Subsequently, a silicon nitride film 1018 is deposited, and further, a silicon oxide film 1019 is deposited thereon, and then a planarization process via a chemical mechanical polishing is conducted to expose a silicon nitride film 1018 (FIG. 6). Next, the silicon nitride film 1018 and the silicon oxide film 1019 are etched to expose the surface of the gate polysilicon electrode 1014 (FIG. 7) Next, nickel is deposited via a sputter process, and then a heat treatment is conducted to form a nickel silicide gate electrode 1020, and the rest of nickel that does not contribute to the silicidation reaction is etched off (FIG. 8). Here, for forming the nickel silicide gate electrode 1020, nickel disilicide (NiSi₂) is formed in case of an n-type MISFET, and tri nickel silicide (Ni₃Si) is formed in case of a p-type MISFET. Then, the silicon oxide film 1019 and the silicon nitride film 1018 are etched to form a stress nitride film 1021 (FIG. 9).

The MIS structure having the nickel silicide gate electrode 1020 and the hafnium-containing nitrided silicate films 1012 and 1013 can be thus manufactured by the above-described process. In particular, two layers of the hafnium-containing nitrided silicate films are deposited for the gate insulating film in the present invention, and in such case, higher mobility and lower leakage current as described in the Description of the present invention can be balanced by controlling atomic concentration of hafnium and nitrogen in the hafnium-containing nitrided silicate film to be deposited.

The hafnium concentration as described here is presented by calculated ratio of hafnium and silicon contained in the hafnium-containing nitrided silicate film, and the nitrogen concentration is presented by calculated ratio of hafnium, silicon, oxygen and nitrogen. More specifically, the hafnium-containing nitrided silicate film is deposited on the silicon substrate, and x-ray photoelectron spectroscopy (XPS) process is utilized to obtain the calculated ratio of the atomic concentration. XPS process is utilized to measure spectrums of hafnium 4f, silicon 2p4+, oxygen is and nitrogen is in the hafnium-containing nitrided silicate film, respectively, and a dimensional area of the obtained spectrum is corrected with a sensitivity coefficient, and the corrected dimensional area of the obtained spectrum is employed to calculate the atomic ratio according to the following formulas:

[hafnium concentration]=[hafnium 4f]/([hafnium 4f]+[silicon 2p4+]); and

[nitrogen concentration]=[nitrogen 1s]/([hafnium 4f]+[silicon 2p4+]+[oxygen 1s]+[nitrogen 1s]).

In such case, in order to eliminate an influence of the presence of the underlying silicon substrate, a hafnium-containing nitrided silicate film is deposited to a thickness of 10 nm before the measurement of the respective elemental concentrations in the present embodiment. Here, the sufficient thickness of the hafnium-containing nitrided silicate film may be that provides no detection of a peak of a spectrum derived from the underlying silicon substrate. In the present invention, a suitable process condition for obtaining desired content ratio in the hafnium-containing nitrided silicate film is determined by the concentration obtained in such method, and the processing time is suitably determined to achieve a thickness of the hafnium-containing nitrided silicate film that exhibits the desired content ratio.

While the specific process for manufacturing the MISFET semiconductor device has been described in the embodiment of the present invention, the process described above is an illustration of the present invention, and various other processes other than the above-described may also be adopted.

For example, while the hafnium-containing nitrided silicate film was manufactured via the MOCVD process in the present example, the above-described structure may also be manufactured by employing, for example, atomic layer deposition (ALD) process. For example, a hafnium-containing source gas of tetrakis ethyl methyl amino hafnium (TEMAH) and a silicon-containing source gas of gaseous tris dimethyl amino silane (3DMAS), and an oxidizing agent of O₃, are alternately supplied to allow respective depositions of the hafnium-containing nitrided silicate film one by one. In the ALD process, the hafnium concentration as described in the present Description can be controlled by suitably adjusting respective flow rates or suitably adjusting frequency of alternate supply.

Further, while nitrogen is implanted in the hafnium-containing nitrided silicate film via the plasma nitridation process in the present embodiment, the same structure as described in the present Description can be also manufactured by suitably defining conditions such as temperature, pressure, processing time, and the like, even if a thermal nitridation process with ammonia is employed. Further, while the oxide film is employed for the base insulating film in the present example, a use of an oxynitride film may also lead to the advantageous effects described in the present Description.

Further, it is needless to say that other analysis technique such as for example, electron energy loss spectroscopy (EELS), secondary ion mass spectroscopy (SIMS) and the like may be employed to conduct the measurements of atomic concentration of metallic element and nitrogen in the gate insulating film.

The method for manufacture the multiple-layered structure of the gate insulating film according to the present invention, in particular, the specific method for depositing films, which provides a controlled hafnium concentration and nitrogen concentration in the hafnium-containing nitrided silicate film, have been described above. As described above, first embodiment of the present invention is directed to depositions of the hafnium-containing nitrided silicate films having different hafnium concentration and nitrogen concentration with an improved controllability.

### Second Embodiment

In second embodiment, a MISFET device was actually manufactured with the method described in first embodiment, and then the electric characteristics of the obtained device were examined, and an adequacy of numerical values defined in the present invention will be discussed on the basis of the obtained electric characteristics. Here, an adequacy of the thickness of the underlying oxide film will be particularly discussed.

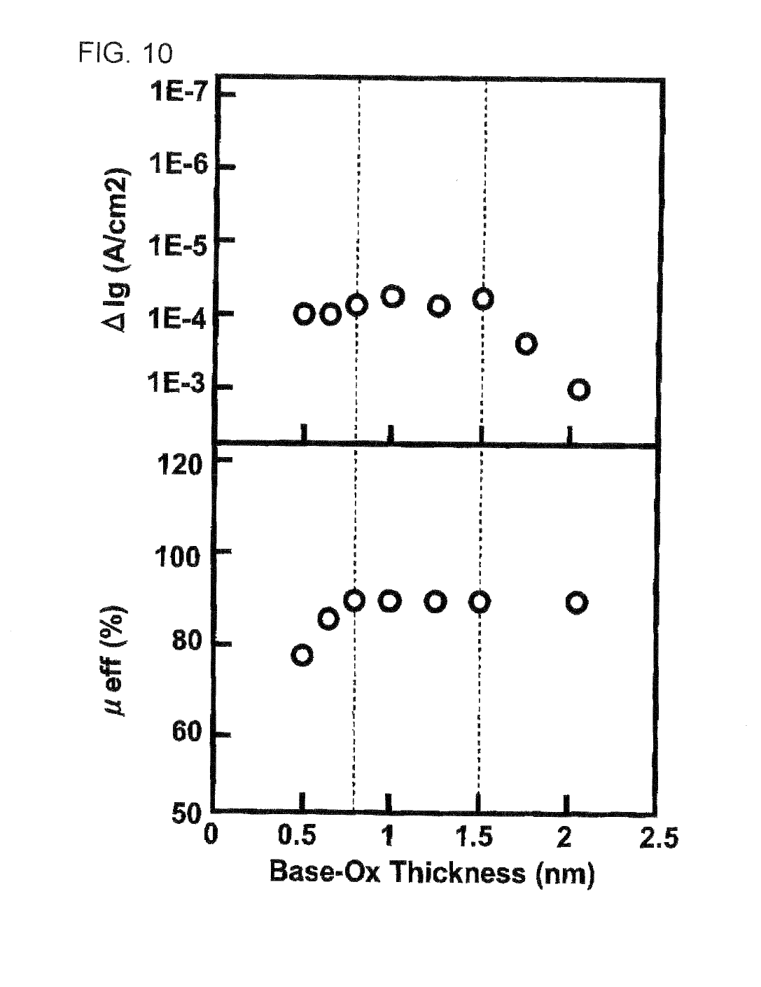

A multiple-layered structure of a gate insulating film, which is similar to that described in first embodiment, was employed in the present embodiment. A thickness of an underlying silicon oxide film 1011 was selected to be within a range of from 0.5 to 2.0 nm. A hafnium concentration of a first hafnium-containing nitrided silicate film 1012 was selected to be 5% and a nitrogen concentration thereof was selected to be 5%, and a thickness thereof was selected to be 1.0 nm. Further, a hafnium concentration of a second hafnium-containing nitrided silicate film 1013 was selected to be 60% and a nitrogen concentration was selected to be 30%, and a thickness thereof was selected to be 1.0 nm.
Relationships of leakage current change (ΔIg) and mobility (μeff) in the n-type MISFET device over a thickness (nm) of the underlying silicon oxide film 1011 is shown in FIG. 10.

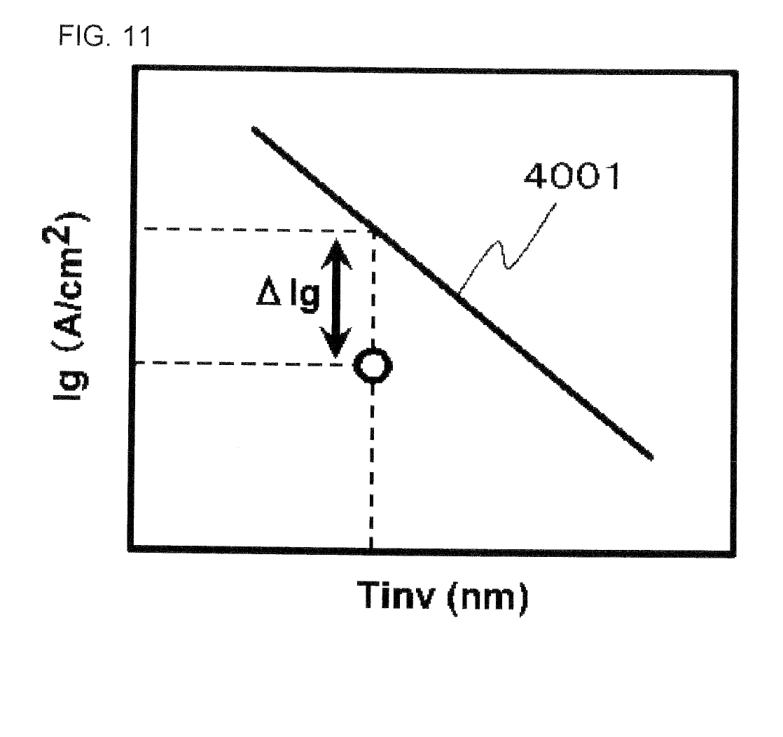

Here, the leakage current change (ΔIg) is determined as a deviation from a leakage current (4001) of the SiO₂ film in the condition of the same inverted capacitance-equivalent thickness when an SiO₂ film is employed for an insulating film (see FIG. 11). More specifically, larger leakage current change presents lower a leakage current as compared with that of the SiO₂ film, and smaller leakage current change presents relatively higher leakage current that is equivalent to that of the oxide film. In addition to above, the inverted capacitance-equivalent thickness was obtained via the following formula with a maximum inverted capacitance (Cₘₐₓ):

(inverted capacitance equivalent thickness)=(ε_{OX}·ε₀·S)/Cₘₐₓ.

Here, S is a dimensional area of the measured MIS capacitance, ε_{OX} is a specific dielectric constant 3.9 of the oxide film, and ε₀ is a dielectric constant in vacuum 8.854×10⁻¹² F/m.

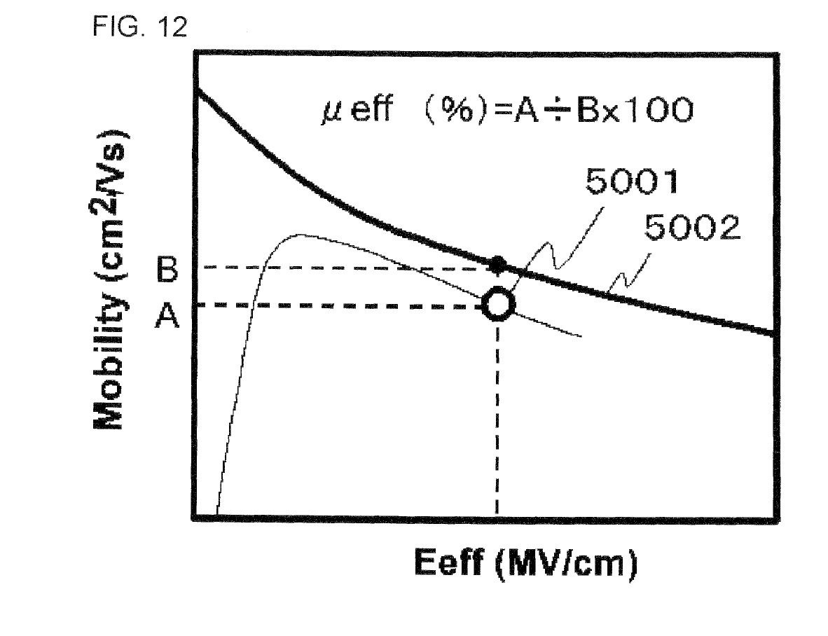

The mobility is calculated as a percentage of a value A (5001) of mobility at an effective electric field in a source voltage of 1.1 V over the value B of the universal curve 5002 (see FIG. 12). More specifically, the mobility is presented by the following formula:

mobility(μeff)=A/B×100(%).

It is understood from FIG. 10 that the mobility is rapidly reduced when the thickness of the underlying oxide film is smaller than 0.8 nm. This is because the first hafnium-containing nitrided silicate film 1012 is closer to the silicon channel, so that fixed charges of hafnium and nitrogen in the first hafnium-containing nitrided silicate film 1012 cause a remote Coulomb-scattering of electron traveling through the channel to considerably reduce the mobility of electron. On the contrary, when the thickness of the underlying oxide film is larger than 1.5 nm, the leakage current is increased. This is because the thickness of the underlying silicon oxide film 1011 of thicker than 1.5 nm causes a decrease in the dielectric constant of the whole gate insulating film, leading to a considerable increase in the leakage current.

As described above, second embodiment shows that the thickness of the underlying silicon oxide film 1011 of preferably within a range of from 0.8 nm to 1.5 nm provides the characteristics of the MISFET with higher mobility and lower leakage current.

### Third Embodiment

In third embodiment, a MISFET device was actually manufactured with the method described in first embodiment, and then the electric characteristics of the obtained device were examined, and an adequacy of numerical values defined in the present invention will be discussed on the basis of the obtained electric characteristics. Here, an adequacy of the thickness of the first hafnium-containing nitrided silicate film 1012 will be particularly discussed.

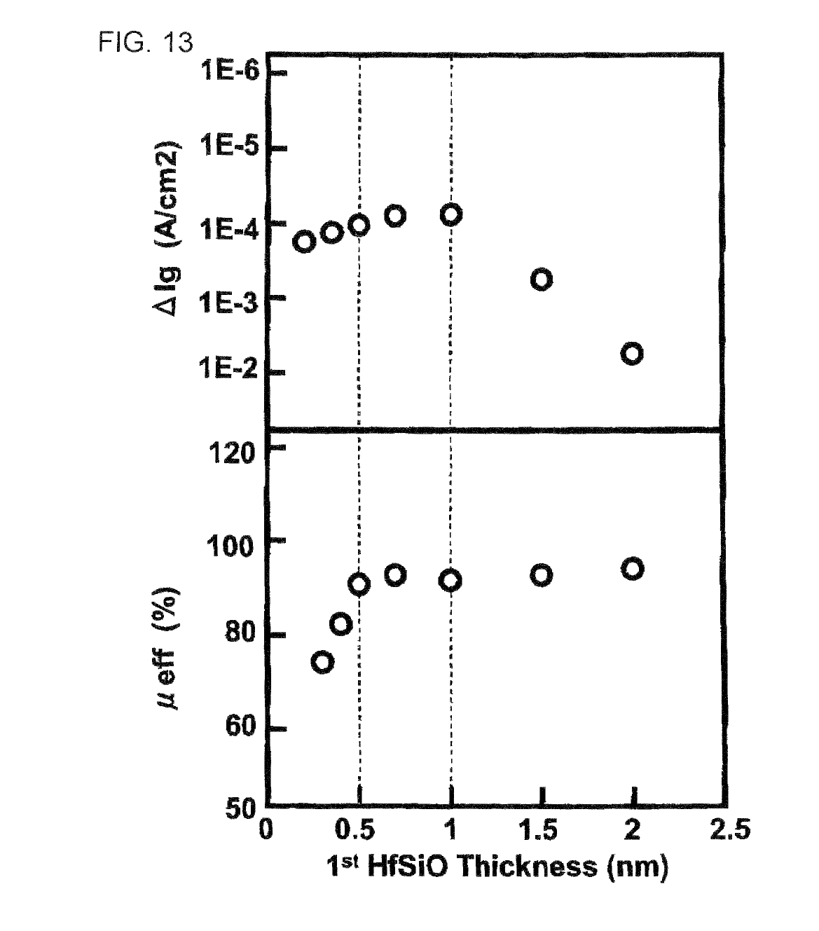

A multiple-layered structure of a gate insulating film, which is similar to that described in first embodiment, was employed in the present embodiment. A thickness of an underlying silicon oxide film 1011 was selected to be 0.8 nm. A hafnium concentration of a first hafnium-containing nitrided silicate film 1012 was selected to be 10% and a nitrogen concentration thereof was selected to be 10%, and a thickness thereof was selected to be within a range of from 0.3 nm to 2.0 nm. Further, a hafnium concentration of a second hafnium-containing nitrided silicate film 1013 was selected to be 50% and a nitrogen concentration was selected to be 20%, and a thickness thereof was selected to be 1.0 nm.
Relationships of leakage current change (ΔIg) and mobility (μeff) in the n-type MISFET device over a thickness of the first hafnium-containing nitrided silicate film 1012 is shown in FIG. 13.

It is understood from FIG. 13 that the mobility is reduced when the thickness of the first hafnium-containing nitrided silicate film 1012 is smaller than 0.5 nm. This is because the second hafnium-containing nitrided silicate film 1013 is closer to the silicon channel, so that hafnium in the second hafnium-containing nitrided silicate film 1013 causes a remote Coulomb-scattering of electron traveling through the channel to considerably reduce the mobility of electron. On the contrary, when the thickness of the first hafnium-containing nitrided silicate film 1012 is larger than 1.0 nm, the leakage current is increased. This is because the thickness of the first hafnium-containing nitrided silicate film 1012 of thicker than 1.0 nm causes a decrease in the dielectric constant of the whole gate insulating film, leading to a considerable increase in the leakage current.

As described above, third embodiment shows that the thickness of the first hafnium-containing nitrided silicate film 1012 of preferably within a range of from 0.5 nm to 1.0 nm provides the characteristics of the MISFET with higher mobility and lower leakage current.

### Fourth Embodiment

In fourth embodiment, a MISFET device was actually manufactured with the method described in first embodiment, and then the electric characteristics of the obtained device were examined, and an adequacy of numerical values defined in the present invention will be discussed on the basis of the obtained electric characteristics. Here, an adequacy of the hafnium concentration in the first hafnium-containing nitrided silicate film 1012 will be particularly discussed.

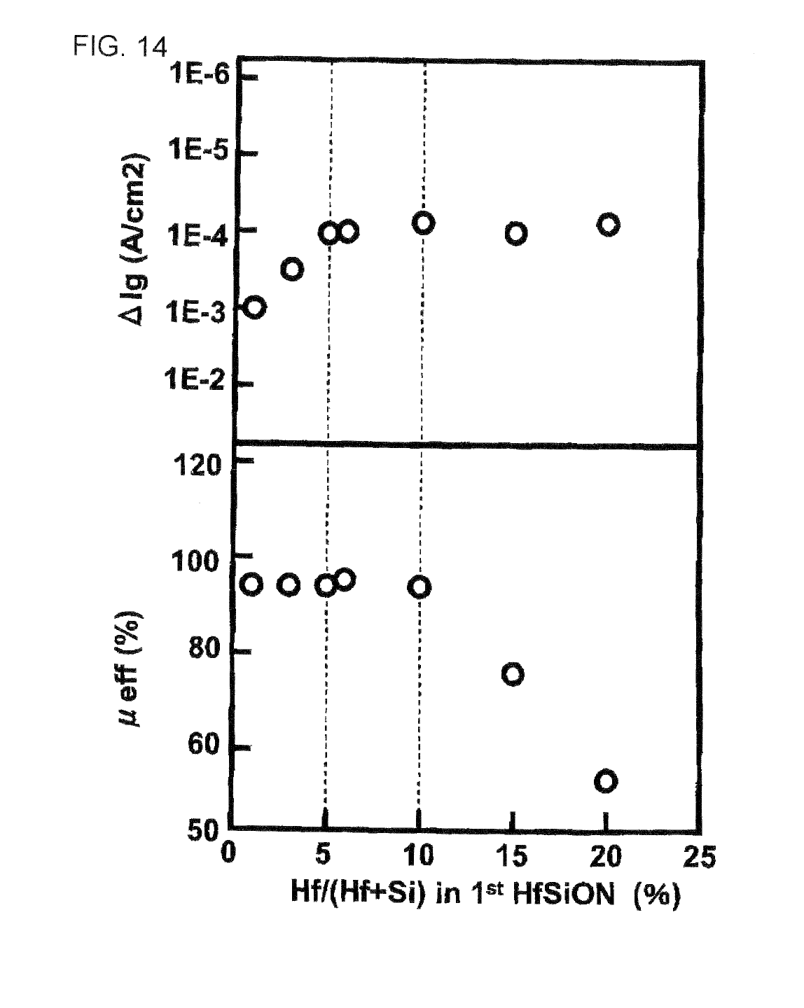

A multiple-layered structure of a gate insulating film, which is similar to that described in first embodiment, was employed in the present embodiment. A thickness of an underlying silicon oxide film 1011 was selected to be 0.8 nm. A hafnium concentration of a first hafnium-containing nitrided silicate film 1012 was selected to be within a range of from 1% to 20% and a nitrogen concentration thereof was selected to be 5%, and a thickness thereof was selected to be 1.0 nm. Further, a hafnium concentration of a second hafnium-containing nitrided silicate film 1013 was selected to be 60% and a nitrogen concentration was selected to be 30%, and a thickness thereof was selected to be 1.0 nm.
Relationships of leakage current change (ΔIg) and mobility (μeff) in the NMISFET device over a hafnium concentration in the first hafnium-containing nitrided silicate film 1012 is shown in FIG. 14. It is understood from FIG. 14 that the leakage current is increased when the hafnium concentration in the first hafnium-containing nitrided silicate film 1012 is lower than 5%, and the mobility is reduced when the hafnium concentration is larger than 10%. This is because the hafnium concentration of lower than 5% causes a decrease in the dielectric constant of the insulating film, leading to a considerable increase in the leakage current. On the other hand, the hafnium concentration of higher than 10% induces a considerable influence of remote Coulomb scattering of hafnium over electron traveling through the channel, deteriorating the mobility of electron.

As described above, fourth embodiment shows that the hafnium concentration in the first hafnium-containing nitrided silicate film 1012 of preferably within a range of from 5% to 10% provides the characteristics of the MISFET with lower leakage current and higher mobility.

### Fifth Embodiment

In fifth embodiment, a MISFET device was actually manufactured with the method described in first embodiment, and then the electric characteristics of the obtained device were examined, and an adequacy of numerical values defined in the present invention will be discussed on the basis of the obtained electric characteristics. Here, an adequacy of the nitrogen concentration in the first hafnium-containing nitrided silicate film will be particularly discussed.

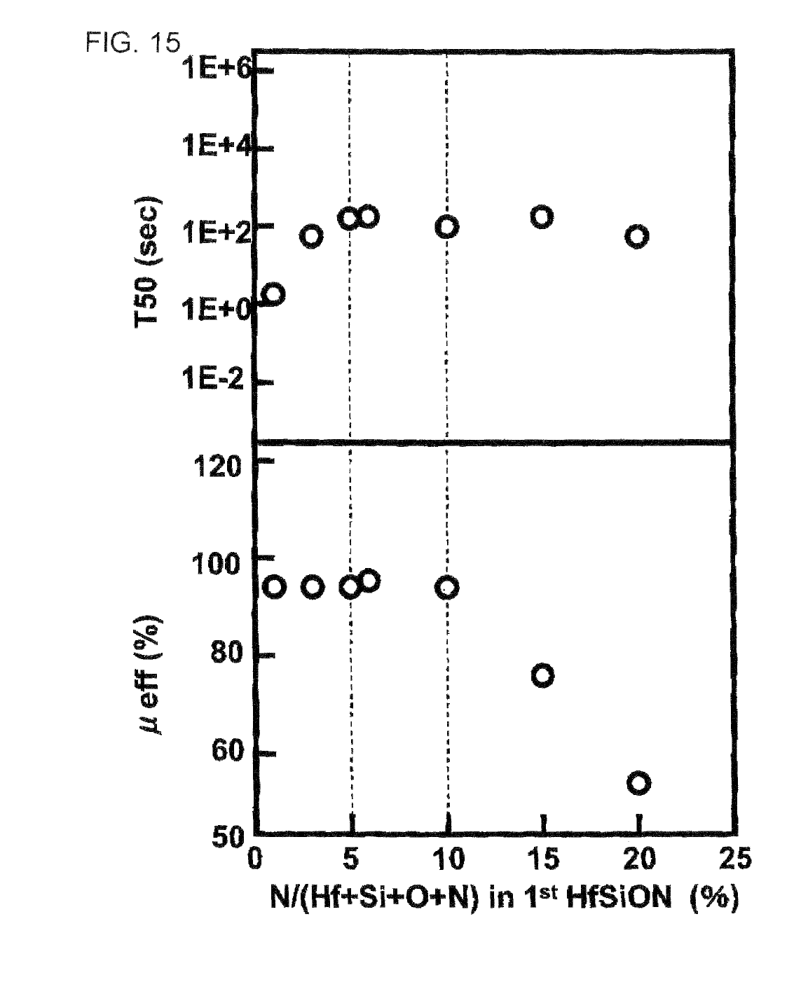

A multiple-layered structure of a gate insulating film, which is similar to that described in first embodiment, was employed in the present embodiment. A thickness of an underlying silicon oxide film 1011 was selected to be 0.8 nm. A hafnium concentration of a first hafnium-containing nitrided silicate film 1012 was selected to be 5% and a nitrogen concentration thereof was selected to be within a range of from 0% to 2%, and a thickness thereof was selected to be 1.0 nm. Further, a hafnium concentration of a second hafnium-containing nitrided silicate film 1013 was selected to be 60% and a nitrogen concentration was selected to be 30%, and a thickness thereof was selected to be 1.0 nm.
Relationships of reliability and mobility of the NMISFET device over a nitrogen concentration in the first hafnium-containing nitrided silicate film 1012 is shown in FIG. 15. Here, the reliability is defined as time required for causing 50% failure (T50) in a time dependent dielectric breakdown (TDDB) testing. It is understood from FIG. 15 that the reliability is decreased when the nitrogen concentration in the first hafnium-containing nitrided silicate film 1012 is lower than 5%, arid the mobility is reduced when the nitrogen concentration is larger than 10%. This is because the nitrogen concentration of lower than 5% causes a decrease in the thermal resistance of the hafnium-containing nitrided silicate film, creating cluster of hafnium in an activation-annealing process and then being crystallized. On the other hand, the nitrogen concentration of 10% or higher induces a considerable influence of fixed charge of atomic nitrogen scattering electron serving as a carrier, deteriorating mobility of electron.

As described above, fifth embodiment shows that the nitrogen concentration in the first hafnium-containing nitrided silicate film 1012 of preferably within a range of from 5% to 10% provides the characteristics of the MISFET with higher mobility and higher reliability.

### Sixth Embodiment

In sixth embodiment, a MISFET device was actually manufactured with the method described in first embodiment, and then the electric characteristics of the obtained device were examined, and an adequacy of numerical values defined in the present invention will be discussed on the basis of the obtained electric characteristics. Here, an adequacy of the thickness of the second hafnium-containing nitrided silicate film 1013 will be particularly discussed.

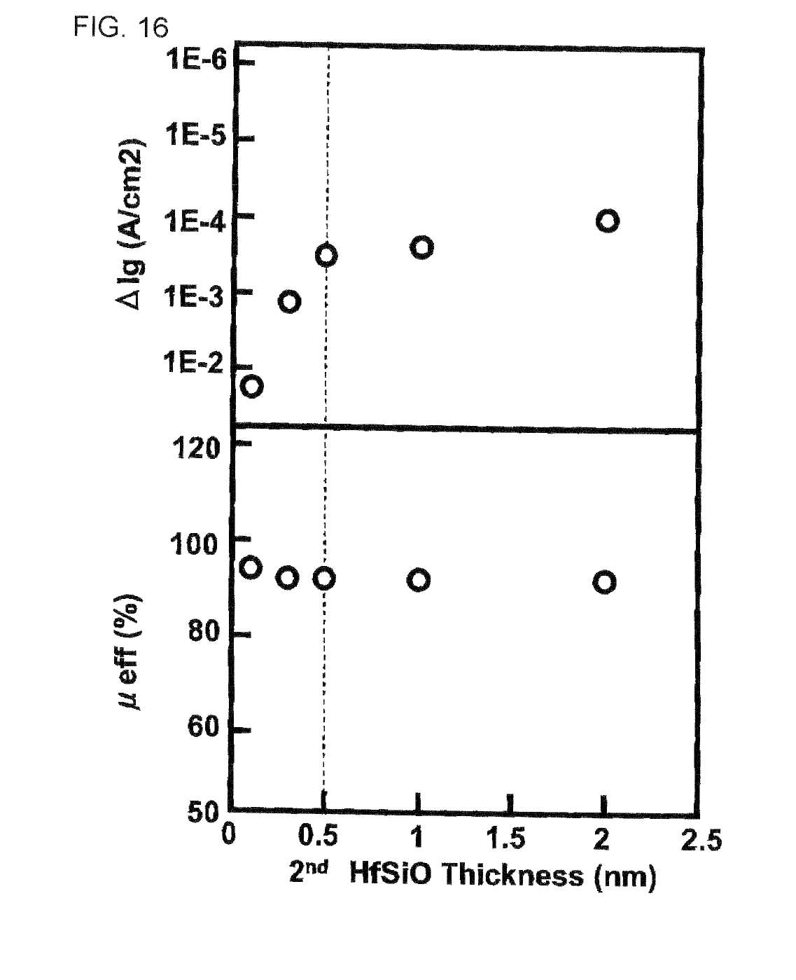

A multiple-layered structure of a gate insulating film, which is similar to that described in first embodiment, was employed in the present embodiment. A thickness of an underlying silicon oxide film 1011 was selected to be 0.8 nm. A hafnium concentration of a first hafnium-containing nitrided silicate film 1012 was selected to be 5% and a nitrogen concentration thereof was selected to be 5%, and a thickness thereof was selected to be 0.5 nm. Further, a hafnium concentration of a second hafnium-containing nitrided silicate film 1013 was selected to be 60% and a nitrogen concentration was selected to be 30%, and a thickness thereof was selected to be within a range of from 0.1 nm to 2.0 nm.
Relationships of leakage current change (ΔIg) and mobility (μeff) in the NMISFET device over a thickness of the second hafnium-containing nitrided silicate film 1013 is shown in FIG. 16.

It is understood from FIG. 16 that the leakage current is considerably increased when the thickness of the second hafnium-containing nitrided silicate film 1013 is lower than 0.5 nm. This is because the thickness of the second hafnium-containing nitrided silicate film 1013 of thinner than 0.5 nm causes a decrease in the dielectric constant of the whole gate insulating film, leading to a considerable increase in the leakage current.

As described above, sixth embodiment shows that the thickness of the second hafnium-containing nitrided silicate film 1013 of preferably not smaller than 0.5 nm provides the characteristics of the MISFET with lower leakage current and higher mobility.

### Seventh Embodiment

In seventh embodiment, a MISFET device was actually manufactured with the method described in first embodiment, and then the electric characteristics of the obtained device were examined, and an adequacy of numerical values defined in the present invention will be discussed on the basis of the obtained electric characteristics. Here, an adequacy of the hafnium concentration in the second hafnium-containing nitrided silicate film 1013 will be particularly discussed.

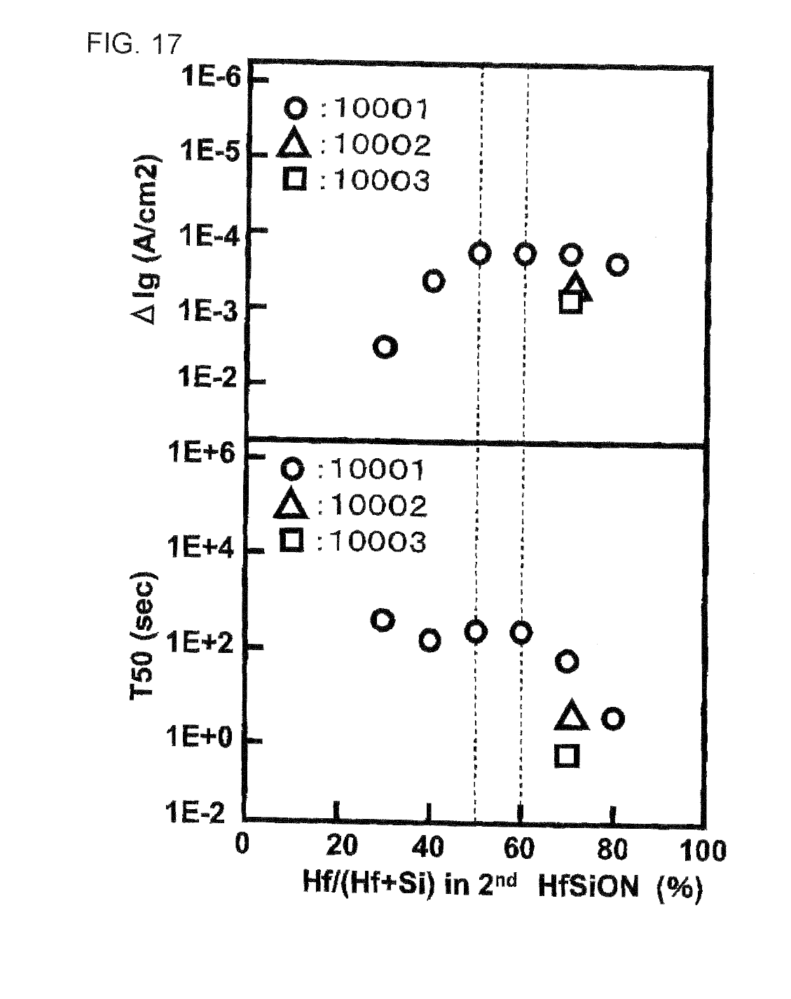

A multiple-layered structure of a gate insulating film, which is similar to that described in first embodiment, was employed in the present embodiment. A thickness of an underlying silicon oxide film 1011 was selected to be 0.8 nm. A hafnium concentration of a first hafnium-containing nitrided silicate film 1012 was selected to be 5% and a nitrogen concentration thereof was selected to be 5%, and a thickness thereof was selected to be 0.8 nm. Further, a hafnium concentration of a second hafnium-containing nitrided silicate film 1013 was selected to be within a range of from 30% to 80% and a nitrogen concentration was selected to be 45%, and a thickness thereof was selected to be 1.0 nm.
Relationships (10001) of leakage current change (ΔIg) and reliability (T50) in the n-type MISFET device over a hafnium concentration of the second hafnium-containing nitrided silicate film 1013 is shown in FIG. 17. It is understood from FIG. 17 that the leakage current is considerably increased when the hafnium concentration in the second hafnium-containing nitrided silicate film 1013 is lower than 50%. This is because the hafnium concentration of the second hafnium-containing nitrided silicate film 1013 of lower than 50% causes a decrease in the dielectric constant of the whole gate insulating film, leading to an increase in the leakage current. On the contrary, the reliability is considerably decreased when the hafnium concentration in the second hafnium-containing nitrided silicate film 1013 is higher than 60%. This is because higher hafnium concentration in the second hafnium-containing nitrided silicate film 1013 causes a decrease in the thermal resistance of the hafnium-containing nitrided silicate film, creating cluster of hafnium in an activation-annealing process and then being crystallized.

Thus, an attempt for inhibiting the crystallization of hafnium even in the case of selecting higher hafnium concentration of 70% in the second hafnium-containing nitrided silicate film 1013 is that the nitrogen concentration in the second hafnium-containing nitrided silicate film 1013 is increased to be 50% and 55%, and the results of such attempt concerning the relationships with the leakage current and the reliability (10002, 10003, respectively) are shown in FIG. 17. It is understood from FIG. 17 that an increased nitrogen concentration causes a considerable ramp-up of the leakage current. This is because the increased nitrogen concentration causes a creation of atomic binding between electroconductive hafnium and nitrogen. Further, it is also found that higher nitrogen concentrations of 50% and 55% considerably deteriorate the reliability. This is because atomic binding between hafnium and nitrogen causes an increased leakage current, creating a leakage pass in the insulating film.

As described above, seventh embodiment shows that the hafnium concentration in the second hafnium-containing nitrided silicate film 1013 of preferably within a range of from 50% to 60% provides the characteristics of the MISFET with lower leakage current and higher reliability.

### Eighth Embodiment

In eighth embodiment, a MISFET device was actually manufactured with the method described in first embodiment, and then the electric characteristics of the obtained device were examined, and an adequacy of numerical values defined in the present invention will be discussed on the basis of the obtained electric characteristics. Here, an adequacy of the nitrogen concentration in the second hafnium-containing nitrided silicate film 1013 will be particularly discussed.

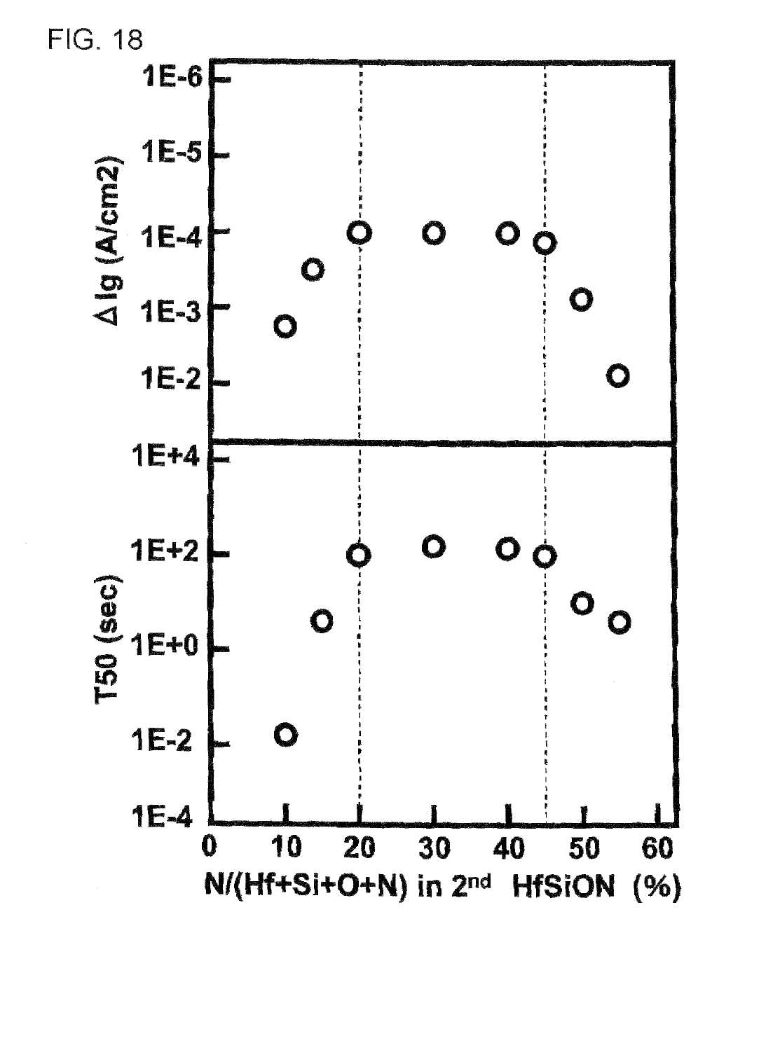

A multiple-layered structure of a gate insulating film, which is similar to that described in first embodiment, was employed in the present embodiment. A thickness of an underlying silicon oxide film 1011 was selected to be 0.8 nm. A hafnium concentration of a first hafnium-containing nitrided silicate film 1012 was selected to be 5% and a nitrogen concentration thereof was selected to be 5%, and a thickness thereof was selected to be 1.0 nm. Further, a hafnium concentration of a second hafnium-containing nitrided silicate film 1013 was selected to be 60% and a nitrogen concentration was selected to be within a range of from 10% to 60%, and a thickness thereof was selected to be 1.0 nm.
Relationships of leakage current change (ΔIg) and reliability in the NMISFET device over a nitrogen concentration of the second hafnium-containing nitrided silicate film 1013 is shown in FIG. 18. It is understood from FIG. 18 that the reliability is considerably decreased when the nitrogen concentration in the second hafnium-containing nitrided silicate film 1013 is lower than 20%. This is because the nitrogen concentration in the second hafnium-containing nitrided silicate film 1013 of lower than 20% creates cluster of hafnium in an activation-annealing process and then being crystallized. Besides, the nitrogen concentration of higher than 45% causes considerably increased leakage current. This is because the increased nitrogen concentration causes a creation of atomic binding between electroconductive hafnium and nitrogen. Further, it is also found that the nitrogen concentrations of higher than 45% considerably deteriorate the reliability. This is because atomic binding between hafnium and nitrogen causes an increased leakage current, creating a leakage pass in the insulating film.

As described above, eighth embodiment shows that the nitrogen concentration in the second hafnium-containing nitrided silicate film of preferably within a range of from 20% to 45% provides the characteristics of the MISFET with lower leakage current and higher reliability.

### Ninth Embodiment

In ninth embodiment, a MISFET was manufactured via a conventional method, and comparisons of electrical characteristics between the conventional device and the device according to the present invention, in order to further describe advantageous effects of the present invention. More specifically, the comparison was made on the device employing a single layer of hafnium-containing nitrided silicate film for a gate insulating film.

A multiple-layered structure of a gate insulating film, which is similar to that described in first embodiment, was employed in the present embodiment. A thickness of an underlying silicon oxide film 1011 was selected to be within a range of from 1.0 nm to 3.0 nm. A hafnium concentration of a first hafnium-containing nitrided silicate film 1012 was selected to be 5% and a nitrogen concentration thereof was selected to be 5%, and a thickness thereof was selected to be 1.0 nm. Further, a hafnium concentration of a second hafnium-containing nitrided silicate film 1013 was selected to be 60% and a nitrogen concentration was selected to be within a range of from 30% to 60%, and a thickness thereof was selected to be 1.0 nm.

Here, for the purpose of comparison, a single layer structure was employed for a section of a multiple-layered structure of a hafnium-containing nitrided silicate film to manufacture a gate insulating film. A hafnium concentration of the single layer hafnium-containing nitrided silicate film was selected to be 60% and a nitrogen concentration was selected to be 30%, and a thickness thereof was selected to be 1.5 nm.

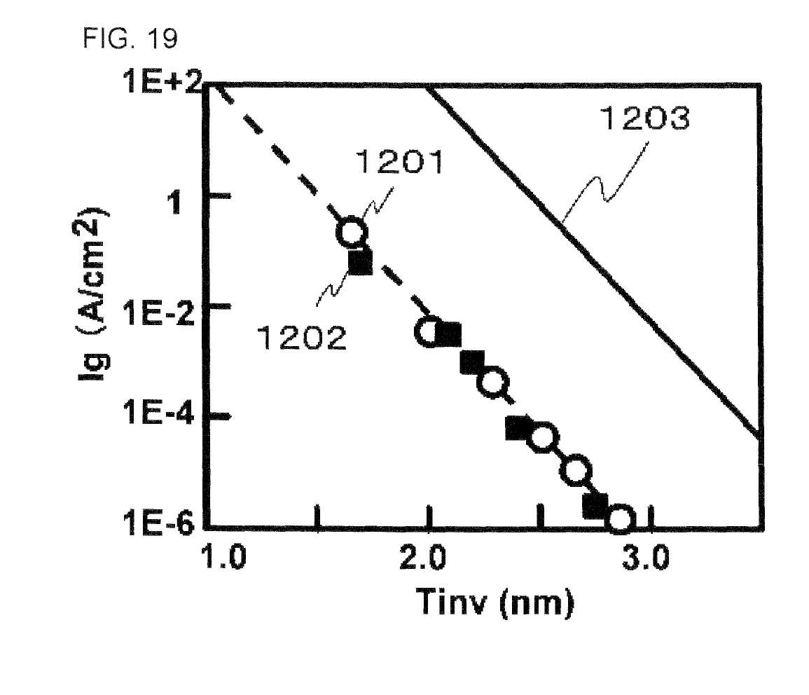

FIG. 19 shows relationships of inverted capacitance-equivalent thickness (Tinv) with leakage current (Ig) for an n-type MISFET over respective gate insulating film structures. It is understood from FIG. 19 that no noticeable difference is present between the results for the multiple-layered structure 1201 and the single layer structure 1202 of the hafnium-containing nitrided silicate film. In addition to above, a relationship (1203) of an inverted capacitance-equivalent thickness with a leakage current for the conventional structure having a polysilicon electrode and a gate oxide film is also shown in the graph for reference.

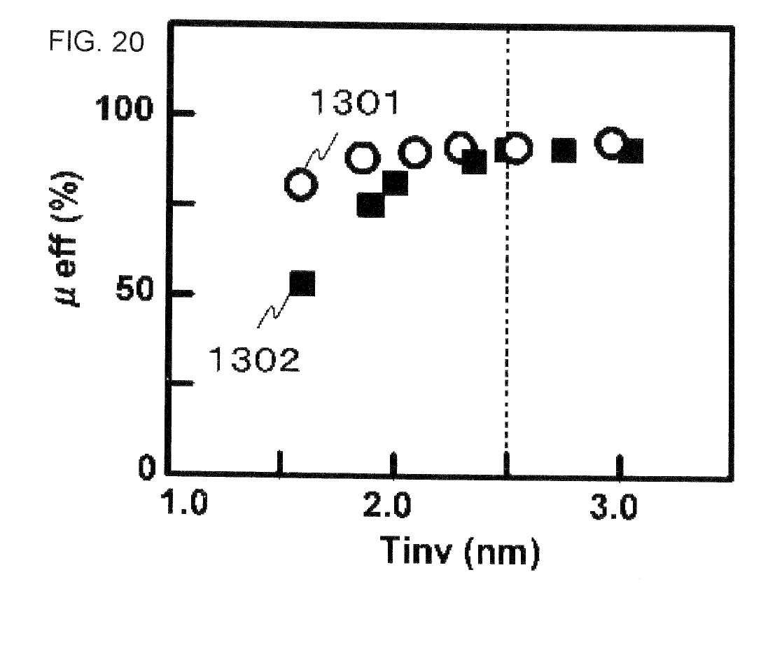

Next, relationships of inverted capacitance-equivalent thickness (Tinv) with mobility (μeff) for respective gate insulating film structures are shown in FIG. 20. It is understood from FIG. 20 that a use of a multiple-layered structure 1301 for the hafnium-containing nitrided silicate film achieves higher mobility than a use of a single layer structure 1302 for the hafnium-containing nitrided silicate film. In particular, considerable difference is appeared in the mobility in the region of the inverted capacitance-equivalent thickness of equal to or smaller than 2.5 nm. Here, in the multiple-layered structure of the hafnium-containing nitrided silicate film, a required thickness of an underlying oxide film for achieving the inverted capacitance-equivalent thickness of 2.5 nm is 1.0 nm. More specifically, the configuration of a gate insulating film is selected to have a thickness of the underlying oxide film of 1.0 nm, a thickness of the first hafnium-containing nitrided silicate of 1.0 nm, and a thickness of the second hafnium-containing nitrided silicate of 1.0 nm, so that an inverted capacitance-equivalent thickness of the gate insulating film of is provides as 2.5 nm.

As described above, ninth embodiment shows that the use of the multiple-layered structure of the hafnium-containing nitrided silicate film as set forth in the present invention achieves higher mobility in the region of the inverted capacitance-equivalent thickness of equal to or smaller than 2.5 nm, without an increase of the leakage current.

### Tenth Embodiment

In tenth embodiment, a MISFET was manufactured via a conventional method, and comparisons of electrical characteristics between the conventional device and the device according to the present invention, in order to further describe advantageous effects of the present invention. More specifically, the comparison was made on the device employing polysilicon for a gate electrode.

A multiple-layered structure of a gate insulating film, which is similar to that described in first embodiment, was employed in the present embodiment. A thickness of an underlying oxide film was selected to be 1.0 nm. A hafnium concentration of a first hafnium-containing nitrided silicate film was selected to be 5% and a nitrogen concentration thereof was selected to be 5%, and a thickness thereof was selected to be 1.0 nm. Further, a hafnium concentration of a second hafnium-containing nitrided silicate film was selected to be 60% and a nitrogen concentration was selected to be within a range of from 30% to 60%, and a thickness thereof was selected to be 1.0 nm.

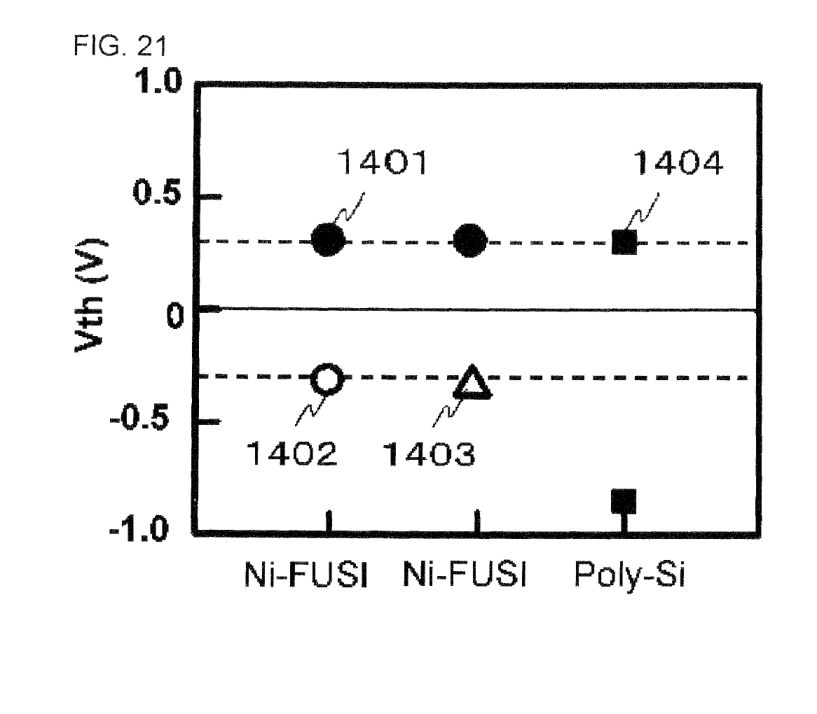

In the present embodiment, a MISFET having a section of a gate electrode with nickel full silicide as described in first embodiment, and a MISFET for comparison having a gate electrode with polysilicon, were manufactured. Here, the nickel full silicide electrode includes nickel disilicide electrode for an n-type MISFET and a tri nickel silicide electrode for a p-type MISFET. In addition to above, levels of impurity injected to the channel regions in the present example were 1×10¹⁸ cm⁻³ for both of the n-type MISFET and the p-type MISFET. Further, the levels of injection to the polysilicon electrode were 1×10¹⁷ cm⁻³ for both of the n-type MISFET and the p-type MISFET. FIG. 21 shows threshold voltages (Vth) in the n-type MISFET and the p-type MISFET for respective gate electrodes. In complementary MISFET (CMISFET), the same absolute value of thresholds is required for both of the n-type MISFET and the p-type MISFET according to principle of operations.

It is understood from FIG. 21 that, when the polysilicon electrode 1404 is employed, absolute value of the threshold voltage (Vth) for the n-type MISFET is considerably different from that for the p-type MISFET. This is because silicon in the polysilicon electrode is bound to hafnium of the hafnium-containing nitrided silicate film at the interface therebetween to create Fermi level pinning, and thus such problem is not solved by changing the level of injection to the channel or the polysilicon electrode. On the contrary, when nickel disilicide 1401 is employed for the n-type MISFET and tri nickel silicide 1402 is employed for the p-type MISFET, the absolute value of threshold of the n-type MISFET is substantially equivalent to that of the p-type MISFET. This is because nickel disilicide is employed for the n-type MISFET and tri nickel silicide is employed for the p-type MISFET to control levels of silicon respectively contained in the electrodes, so that a reduced bonding of silicon with hafnium created in the interface of the hafnium-containing nitrided silicate film and the electrode is achieved. More specifically, tri nickel silicide of relatively lower atomic ratio of silicon is employed for the p-type MISFET to release Fermi level pinning, so that the absolute value of the threshold voltage for the p-type MISFET is adjusted to be substantially equivalent to that for the n-type MISFET.

FIG. 21 shows results of a threshold voltage 1403, which was obtained by employing an FUSI electrode having an atomic ratio of Ni₃₁Si₁₂ for the electrode of the p-type MISFET. It can be understood from the graph that the threshold voltage thereof is equivalent to that of tri nickel silicide. This is because atomic ratio of Ni₃₁Si₁₂ is extremely closer to tri nickel silicide layer, so that the level of bonding of silicon with hafnium created in the interface of the electrode and the hafnium-containing nitrided silicate film is not very different in either of employing Ni₃₁Si₁₂ and employing tri nickel silicide. Therefore, even if Ni₃₁Si₁₂ is employed for the p-type MISFET, absolute value of threshold voltage for the p-type MISFET can be provided to be equivalent to that for the n-type MISFET.

As described above, Composition control of a gate insulating film having a thickness of this proposal is conducted, and further, nickel disilicide (NiSi₂) is employed for the NMISFET and tri nickel silicide (Ni₃Si) is employed for the p-type MISFET or 31-nickel 12-silicide (Ni₃₁Si₁₂) is employed for the p-type MISFET, so that the absolute value of threshold voltage for the n-type MISFET can be provided to be equivalent to that for the p-type MISFET, unlikely as the case of employing the polysilicon electrode.

While nickel disilicide, tri nickel silicide and 31-nickel 12-silicide are employed in the present embodiment, other metallic electrode materials may also be employed to achieve the same advantageous effects as described in the Description of the present invention. For example, nickel silicide (NiSi), di nickel silicide (Ni₂Si) and the like may alternatively be employed to suitably adjust a target threshold voltage, thereby obtaining the same advantageous effects as described in the Description of the present invention.

As described above, tenth embodiment shows that the use of the electrode materials of nickel disilicide for the n-type MISFET and of tri nickel silicide for the p-type MISFET in the multiple-layered structure of the hafnium-containing nitrided silicate film as described in the present invention, so that the absolute values of the respective threshold voltages can be provided to be equivalent, satisfying the characteristics required for the CMISFET.

While embodiments of the present invention has been fully described above in reference to the annexed figures, it is intended to present these embodiments for the purpose of illustrations of the present invention only, and various modifications other than that described above are also available.

It is apparent that the present invention is not limited to the above embodiment, and may be modified and changed without departing from the scope and spirit of the invention.

What is claimed is:

1. A semiconductor device comprising one or more metal-insulator-semiconductor field effect transistors (MISFETS) each including:
a gate insulating film composed of a silicon oxide film, a first hafnium-containing nitrided silicate film, and a second hafnium-containing nitrided silicate film which are sequentially deposited on a substrate; and
a gate structure having an electrode consisting of a metal silicide deposited on said gate insulating film,
wherein:
said first hafnium-containing nitrided silicate film has a hafnium concentration in a range from 5 to 10% and has a nitrogen concentration in a range from 5 to 10%;
said second hafnium-containing nitrided silicate film has a hafnium concentration in a range from 50 to 60% and has a nitrogen concentration in a range from 20 to 45%; and
said gate insulating film has a thickness in a range from 1.8 to 3.0 nm.

2. The semiconductor device as set forth in claim 1, wherein said silicon oxide film has a thickness in a range from 0.8 nm to 1.5 nm.

3. The semiconductor device as set forth in claim 1, wherein said first hafnium-containing silicate film has a thickness in a range from 0.5 nm to 1.0 nm.

4. The semiconductor device as set forth in claim 1, wherein a thickness of said second hafnium-containing nitrided silicate film is equal to or larger than 0.5 nm.

5. The semiconductor device as set forth in claim 1, wherein metal silicide constituting said metal silicide electrode is nickel silicide.

6. The semiconductor device as set forth in claim 1, wherein said metal-insulator-semiconductor field effect transistors are composed of a p-type MISFET and an n-type MISFET, wherein:
said p-type MISFET includes the metal silicide electrode consisting of tri-nickel silicide (Ni₃Si) or Ni₃₁Si₁₂; and
said n-type MISFET includes the metal silicide electrode consisting of nickel disilicide (NiSi₂).
